(19) United States
(12) Patent Application Publication
(10) Pub. No.: US 2020/0375067 A1
(43) Pub. Date: Nov. 26, 2020

(54) COOLING SURFACE MOUNT FOR RACK SERVERS ALLOWING MODULAR RESOURCE CONFIGURATION

(71) Applicant: SolidRun Ltd., Yokneam Illit (IL)

(72) Inventors: Atai ZIV, Matan (IL); Rabeeh KHOURY, Tarshisha (IL); Kossay OMARY, Nazareth (IL); Avi LEVY, YOKNEAM ILLIT (IL)

(73) Assignee: SolidRun Ltd., Yokneam Illit (IL)

(21) Appl. No.: 16/886,303

(22) Filed: May 28, 2020

Related U.S. Application Data
(63) Continuation-in-part of application No. 16/090,250, filed on Sep. 30, 2018.
(60) Provisional application No. 62/853,346, filed on May 28, 2019.
(60) Provisional application No. 62/316,048, filed on Mar. 31, 2016.

(51) Int. Cl. H05K 7/20; F28F 3/12

(52) U.S. Cl. CPC H05K 7/20836; F28D 2021/0029; F28F 3/12

(57) ABSTRACT

An active fluid cooled heatsink assembly for modular components is disclosed. The active fluid heatsink assembly includes a fluid cooled heatsink, the heatsink further comprising: an inlet, an outlet, and a surface, wherein fluid passing through the heatsink is received by the inlet at a first temperature and expelled from the outlet at a second temperature, wherein the second temperature is higher than the first temperature; and at least one resource adapter, each resource adapter further comprising a first surface having a shape which conforms to a corresponding electronic resource of at least one electronic resource and a second surface having a shape corresponding to at least a portion of the surface of the fluid cooled heatsink, wherein each resource adapter exchanges heat from the corresponding electronic resource to the fluid cooled heatsink, and wherein the at least one resource adapter is mounted on the surface of the fluid cooled heatsink.

### CROSS-REFERENCE TO RELATED APPLICATIONS

This application claims the benefit of U.S. Provisional Application No. 62/853,346 filed on May 28, 2019, the contents of which are hereby incorporated by reference. The application is also related to It is also a continuation-in-part of U.S. patent application Ser. No. 16/090,250, incorporated herein by reference.

### TECHNICAL FIELD

The disclosure generally relates to heat dissipation for modular computing and, particularly, to elements for heat dissipation.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section. Similarly, issues identified with respect to one or more approaches should not be assumed to have been recognized in any prior art on the basis of this section, unless otherwise indicated.

Computing elements such as processors tend to generate heat as part of their normal operation. Heat can be a serious issue to contend with, as overheating may damage microelectronics, causing, for example, circuits to fuse and become unusable. Various forms of heat sinks or heat exchanges are therefore implemented in order to overcome this problem. This is especially true of data centers where there are many such elements which are all in a similar environment, all requiring heat exchange.

It would therefore be beneficial to find a solution which could improve the performance of a heat exchanger and, even more so, one that could improve performance of a data center in general.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the terms “some embodiments” or “certain embodiments” may be used herein to refer to a single embodiment or multiple embodiments of the disclosure.

Certain embodiments disclosed herein include an active fluid cooled heatsink assembly for modular components. The active fluid cooled heatsink assembly comprises a fluid cooled heatsink, the heatsink further comprising: an inlet, an outlet, and a surface, wherein fluid passing through the heatsink is received by the inlet at a first temperature and expelled from the outlet at a second temperature, wherein the second temperature is higher than the first temperature; and at least one resource adapter, each resource adapter further comprising a first surface having a shape which conforms to a corresponding electronic resource of at least one electronic resource and a second surface having a shape corresponding to at least a portion of the surface of the fluid cooled heatsink, wherein each resource adapter exchanges heat from the corresponding electronic resource to the fluid cooled heatsink, and wherein the at least one resource adapter is mounted on the surface of the fluid cooled heatsink.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is an isometric schematic illustration of a front top view of a server rack resource, implemented in accordance with an embodiment.

FIG. 2A is a schematic illustration of a side view of the server rack resource, in accordance with an embodiment.

FIG. 2B is a schematic illustration of a top view of the server rack resource with a heatsink adapter, implemented in accordance with an embodiment.

FIG. 3A is a schematic illustration of a side view of a fluid-cooled heatsink unit coupled with a plurality of server rack resources, implemented in accordance with an embodiment.

FIG. 3B is a schematic illustration of a top view of a fluid cooled heatsink unit coupled with a plurality of server rack resources, implemented in accordance with another embodiment.

FIG. 3C is a schematic illustration of a top view of a fluid cooled heatsink unit coupled with a plurality of server rack resources, implemented in accordance with another embodiment.

FIG. 4 is a schematic illustration of the management module implemented according to an embodiment.

### DETAILED DESCRIPTION

Below, exemplary embodiments will be described in detail with reference to accompanying drawings so as to be easily realized by a person having ordinary skill in the art. The exemplary embodiments may be embodied in various forms without being limited to the exemplary embodiments set forth herein. Descriptions of well-known parts are omitted for clarity, and like reference numerals refer to like elements throughout.

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality.

A novel heat dissipation device allows for modular electronic resource configuration, improving resource utilization and heat dissipation capabilities. A heatsink includes a cavity into which a fluid may enter at a first temperature and exit at a higher temperature, having exchanged heat with one or more electronic resources coupled thereto. Each electronic resource is fitted with a resource adapter which has a first geometry which is unique to the electronic resource, and a second geometry which ensures maximum contact with a surface of the heatsink. This approach allows connecting modular resources to the heatsink and coupling the modular resources with a controller which allows client devices to access the electronic resources.

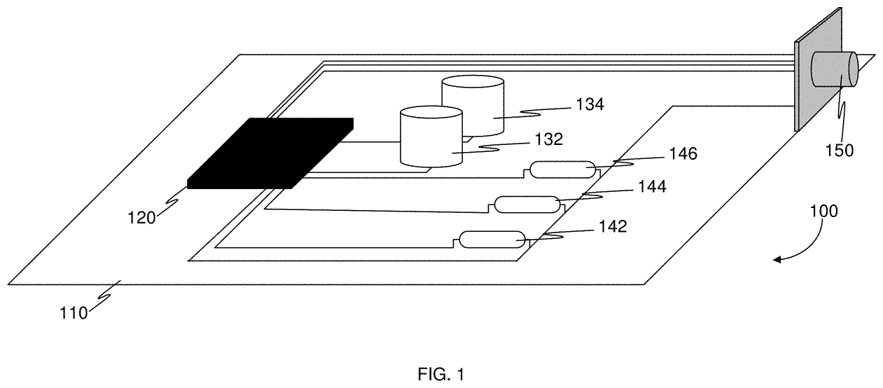

FIG. 1 is an isometric schematic illustration of a front top view of a server rack resource 100, implemented in accordance with an embodiment. A server rack resource 100 typically includes a printed circuit board (PCB) or other suitable substrate 110 for affixing electronic components. Electronic components may include, as examples and without limitation, diodes, resistors, capacitors, solenoids, microchips, processors, and other, like, components. In the exemplary embodiment, the resource 100 includes a substrate 110, to which a processor 120, a first capacitor 132, a second capacitor 134, a first resistor 142, a second resistor 144, a third resistor 146, and a communication port 150 are all affixed. For example, the resource 100 depicted in the example embodiment may provide processing power supplied by the processor 120. A manufacturer would typically produce hundreds, thousands, or millions of such units, in which components are placed identically on the substrate 110. The resource 100 is suitable for placement in a server rack, where it may be connected, through the communication port 150, for example, to a plurality of other similar resources 100, which may be provided to client devices. The various components are connected by channels or wires, which may be embedded in the substrate 110.

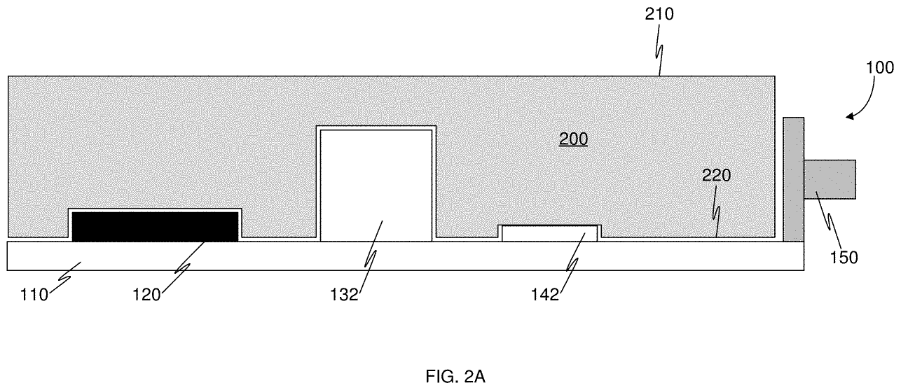

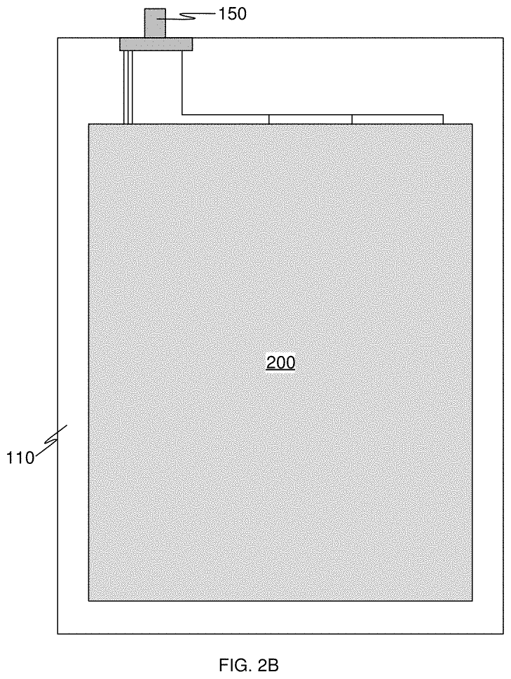

FIG. 2A is a schematic illustration of a side view of the server rack resource 100, in accordance with an embodiment. In this view, a heatsink adapter 200 is added on top of the resource 100. The heatsink adapter 200 has a top surface 210 and a substantially opposed bottom surface 220. The bottom surface 220 may be defined at least partially by the negative space created between the electronic components. Such a configuration ensures that the bottom surface 220 is in physical proximity to as much of the resource 100 as possible. For heat dissipation, the amount of contact between two surfaces is directly proportional to the degree of heat dissipation. The heatsink adapter 200 is a passive heat exchanger which is used to dissipate heat generated by the electronic components of the resource 100. For example, processors, whether CPUs or GPUs, and power transformers are components which require additional heat dissipation, as the components themselves cannot dissipate heat fast enough to remain at an operating temperature. Operating at high temperatures can lead to short circuits and irreparable damage to the components. In extreme cases, such high-temperature operation can also create fire hazards. In some embodiments, the bottom surface 220 may cover a portion, but not all, of the components of the resource 100. In other embodiments, the bottom surface 220 may cover the entire resource 100, including the substrate 110. The top surface 210 may be flat, and may be configured for contact with a heat exchange.

FIG. 2B is a schematic illustration of a top view of the server rack resource 100 with a heatsink adapter 200, implemented in accordance with an embodiment. In this exemplary embodiment, the heatsink adapter 200 does not cover the entire substrate 110, leaving, for example, the communication port 150, exposed. In some embodiments, this may be acceptable as certain components do not require heat dissipation or, alternatively, require physical access which may not be achieved if a heat sink is placed thereon.

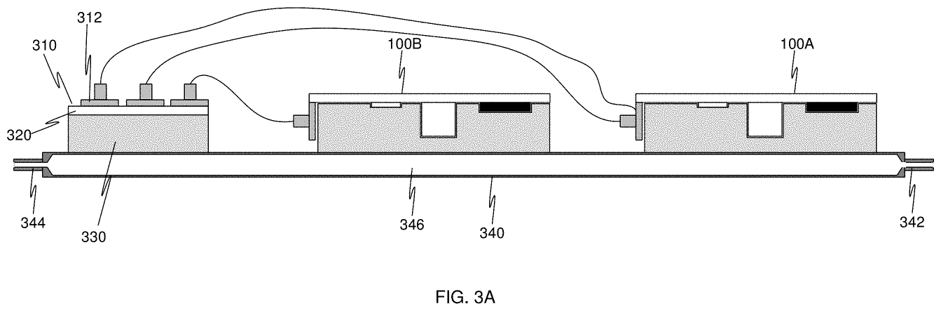

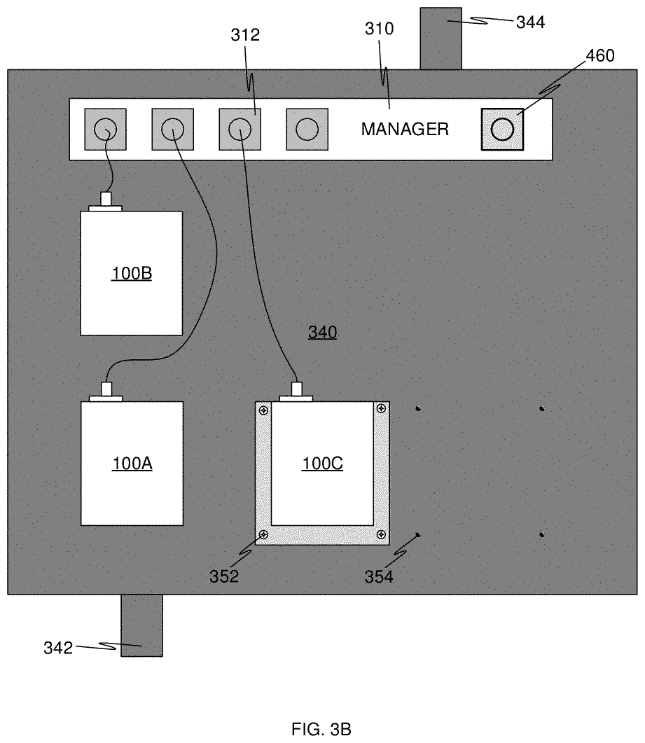

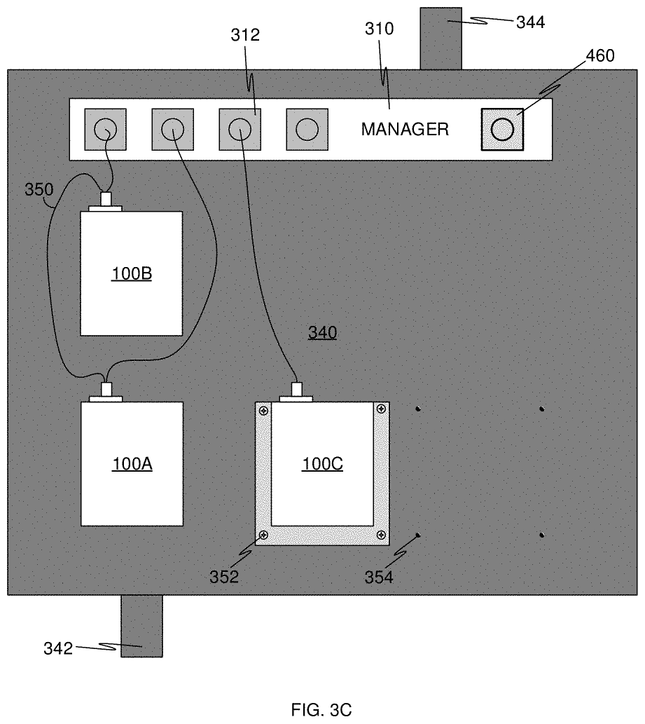

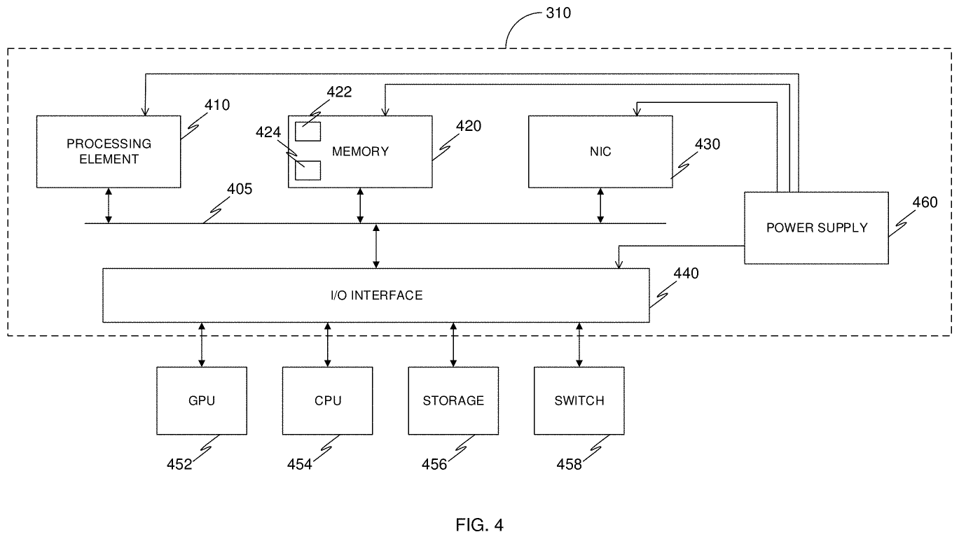

FIG. 3A is a schematic illustration of a side view of a fluid-cooled heatsink 340 unit coupled with a plurality of server rack resources, 100A and 100B (hereinafter, “resources” 100), implemented in accordance with an embodiment. A fluid-cooled heatsink 340 includes an inlet 342 for allowing fluid at a first temperature to enter a chamber 346 of the heatsink 340, and an outlet 344 for allowing the fluid to exit at a second temperature, where the second temperature is higher than the first temperature, due to the fluid absorbing heat from at least one resource, such as the resource 100A. As a result, heat flows from the resource 100 (or components of the resource 100 which generate heat) to the heatsink adapter to the heatsink 340, where it is extracted via heat exchange with the fluid. The fluid may be, as examples and without limitation, a cooled gas, a liquid, an engineered fluid, or another, like, fluid. An engineered fluid may be adapted, for example, with high dielectric performance, enabling contact with electronic components without damaging them, an application to which fluids including perfluorocarbons (PFCs), among other fluids, may be applicable. The fluid may exit the chamber 346 through the outlet 344 into another heat exchange, where the fluid is relieved of at least some excess heat, and then recycled back into the inlet 342 to repeat the process. The adapter allows the manufacture of a heatsink 340 with a geometry which allows connection to a maximum number of resources 100 while dissipating a large amount of heat generated by those resources 100. In the illustrative embodiment, the heatsink 340 has a flat surface which is parallel to the flat surface of the heatsink 340 adapter. However, it should be readily understood that, in other embodiments, different geometries may be used, such as, for example, geometries which allow the adapter a larger surface area for connection to the heatsink 340, or geometries which allow for fastening the adapter to the heatsink 340. In some embodiments, a thermally conductive compound, such as thermal grease, may be used between the resource 100 and the adapter, and between the adapter and the heatsink 340. The thermally conductive compound may be electrically insulating or, in some embodiments, electrically conducting. The compound may be used to eliminate any gaps between the heat exchanges, as any lack of contact (i.e. air between the surfaces) is not thermally conductive and would, therefore, permit less heat dissipation. Use of the adapter also allows a modular approach to constructing server racks or blades. While prior art solutions may rely on some set configuration of blade or rack, the proposed solution can implement more dynamic requirements. For example, if a group of processors typically occupies an entire rack or blade unit, but the application does not require such a quantity of processors, then, by implementing the proposed solution, the space used by the redundant processors may be used for other components, such as storage, memory, GPUs, and the like. The heatsink 340 unit is further coupled with a management module 310, which includes a heatsink adapter 330, and a substrate 320, on which a plurality of connectors, such as the connector 312, may be implemented, which allow for communication between the management module 310 and the resources, such as the resource 100B. The management module 310 is discussed in greater detail with respect to FIG. 4 below.

FIG. 3B is a schematic illustration of a top view of a fluid cooled heatsink 340 unit coupled with a plurality of server rack resources, 100A, 100B, and 100C (hereinafter, “resources” 100), implemented in accordance with another embodiment. The heatsink 340 is coupled with a plurality of resources, 100A, 100B, and 100C, each of which is connected to a management module 310. The heatsink adapters of resources 100A and 100B have a smaller area than the substrate, while the heatsink 340 adapter of resource 100C is larger than the substrate, 320, of FIG. 3A, above. This may allow, for example, for mechanical coupling of the heatsink 340 adapter to the heatsink 340. This coupling may be achieved via a mechanical fastener, such as a screw 352 or a bolt. A fastener may be affixed through a hole or perforation, such as the hole 354, which may or may not be threaded, depending on the type of mechanical fastener used.

It should be noted that, though the terms ‘hole’ and ‘perforation’ are used, it is not always advantageous to have a hole 354 bore through the entire thickness of the heatsink 340, as this would either allow fluid to extrude from the hole 354 or, more likely, be defined by a solid area of the heatsink 340 through which fluid does not flow, thereby hindering its ability to expel heat. It may, therefore, be more useful to have fastener holes 354, the depths of which are such that the fastener holes 354 do not perforate the chamber through which fluid is flowing. EPMs (electro-permanent magnets) may be used as fastening devices, replacing the screws 352 or other fasteners. Further, the heatsink 340 unit may include a management module 310, such as the management module, 310, described in greater detail with respect to FIG. 3C, below. The management module 310 further includes a power supply 460 which may be configured to connect to a power grid and to supply the management module 310 and resources 100 with electric power. In an embodiment, the resources 100 may connect directly to the power supply 460 and, in other embodiments, the resources 100 are provided with power through a cable which connects the resources 100 with the management module 310.

FIG. 3C is a schematic illustration of a top view of a fluid cooled heatsink 340 unit coupled with a plurality of server rack resources, 100A, 100B, and 100C (hereinafter, “resources” 100), implemented in accordance with another embodiment. In the exemplary embodiment, one or more of the resources 100 are further connected to one another, so that a first resource 100 may control, communicate with, or otherwise utilize a second resource 100. In the example, all the modules are initially connected to the management module 310.

The management module 310 may then initiate an instruction set to convey how to connect resources 100 to one another. Such a configuration may allow distribution of memory, computing power, and the like. In an embodiment, the management module 310 may initiate a signal, such as configuring, at each terminal of a connection, an LED to blink or turn on continuously until the connection is made, configuring an included speaker to emit a tone or other auditory indicator, or configuring both an LED and a speaker to serve as indicators. For example, resource 100A and resource 100B are connected to the management module 310 by an operator. The management module 310 then determines that two resources 100A and 100B should be connected. The management module 310 may instruct an LED (not shown) on a first resource 100A, and an LED (not shown) on a second resource 100B, to blink, indicating to the human operator that a connection 350 should be made.

Once the human operator connects the first resource 100A to the second resource 1008, the management module 310 may instruct the LEDs (not shown) to stop blinking. In some embodiments, multiple resources 100 may be connected to one another and multiple LEDs (not shown) may be used in a plurality of colors to indicate to the operator an amount of connections 350 that need to be made. In some embodiments, the management module 310 may signal that connections 350 should be made in a specific order by causing different LEDs (not shown) to blink after one or more pairs of resources 100 are indicated as having been connected. In some embodiments, electro-permanent magnets may be used to make connections so that, if a connecting cable is pulled or yanked, the disconnection would not alter positions of the resources or cause other stresses. In certain embodiments, some resources 100 may be coupled with one another without being connected to a management module 310.

FIG. 4 is a schematic illustration of the management module 310 implemented according to an embodiment. The management module 310 includes at least one processing element 410 such as, for example, a central processing unit (CPU). In an embodiment, the processing element 410 may be, or may be a component of, a larger processing unit implemented with one or more processors. The one or more processors may be implemented as any combination of general-purpose microprocessors, microcontrollers, digital signal processors (DSPs), field programmable gate array (FPGAs), programmable logic devices (PLDs), controllers, state machines, gated logic components, discrete hardware components, dedicated hardware finite state machines, or other suitable entities which can perform calculations or other manipulations of information.

The processing element 410 is coupled via a bus 405 to a memory 420. The memory 420 may include a first memory portion 422 that contains instructions that, when executed by the processing element 410, performs the methods described in greater detail herein. The memory 420 may be further used as a working scratch pad for the processing element 410, as a temporary storage, and for other, like, functions. The memory 420 may be volatile memory such as, but not limited to, random access memory (RAM), or non-volatile memory (NVM), such as, but not limited to, flash memory or other, like, types of memory. The memory 420 may further include a second memory portion 424 containing configuration instructions for each of a predetermined set of modular hardware elements, such as the GPU 452, the CPU 454, the storage 456, and the network switch 458, which may be connected to the management module 310.

The processing element 410 may be coupled to a network interface controller (NIC) 430. The NIC 430 provides connectivity between the management module 310 and a network, between the management module 310 and at least another management module 310, and other, like, connections. In an embodiment, the network may be configured to provide connectivity of various types, as may be necessary, including, but not limited to, wired and/or wireless connectivity, including, for example, local area networks (LANs), wide area networks (WANs), metro area networks (MANs), connectivity with the worldwide web (WWW), connectivity with the internet, cellular connectivity, and any combination thereof.

By providing such connectivity, the NIC 430 allows modular hardware elements, such as the GPU 452, the CPU 454, the storage 456, and the network switch 458, coupled with the management module, to be accessed by client devices. The processing element 410 is further coupled with an I/O interface 440. The I/O interface 440 allows the processing element 410 to connect with a plurality of modular hardware elements, such as the GPU 452, the CPU 454, the storage 456, and the network switch 458.

In an embodiment, the I/O interface 440 and the bus 405 may be a single physical component. A power supply 460 may be configured to provide connections to a power grid and to supply the components of the management module with electric power. The power supply 460 is coupled with the processing element 410, the memory 420, the NIC 430, and the I/O interface 440. The I/O interface 440 may provide power to the various modular hardware elements, such as the GPU 452, the CPU 454, the storage 456, and the network switch 458, connected thereto. A modular hardware element may be a GPU 452, a CPU 454, a storage 456, a network switch 458, or another, like, component. It may be readily understood that one or more, or none, of each of the modular hardware elements depicted, such as the GPU 452, the CPU 454, the storage 456, and the network switch 458, may be utilized.

It should be noted that the dynamic system depicted allows for the tailoring of modular hardware elements, such as the GPU 452, the CPU 454, the storage 456, and the network switch 458, to provide, in a more exact manner, the capabilities required. Thus, if an application requires four GPUs 452 and two storage 456 units, the components may be mounted on the same type of cooling heatsink (not pictured) as in any other configuration, assuming such a configuration physically fits on the heatsink, and, through, the management module 310, the modular hardware elements, such as the GPU 452, the CPU 454, the storage 456, and the network switch 458, are externally exposed in a manner where they can be utilized by a client device. In prior art solutions, modular hardware elements, such as the GPU 452, the CPU 454, the storage 456, and the network switch 458, are typically available as prearranged arrays, which may be larger or smaller than what an application requires or specifies. In a per-unit solution, an implementation may reduce or eliminate redundant components. For example, if GPU units 452 are offered in arrays of sixteen units, and storage units 456 are offered in arrays of ten units, it would be necessary to get one of each unit, in addition to a power supply for each.

In this example embodiment, each array would take up a space of three U (a unit of measure in a standard 19-inch rack). By utilizing the proposed solution, an array may be constructed with a space requirement of two U, as it would comprise the heatsink unit (not pictured), to which only the needed modular hardware elements, such as the GPU 452, the CPU 454, the storage 456, and the network switch 458, would be attached. Such a configuration would provide for savings of both physical space which, in some locations, such as city centers, is in extremely high demand, as well as possible financial savings by requiring the purchase of fewer components, as well as the ability to fit a greater number of applications into a standard rack.

The processing element 410, the memory 420, or both, may also include machine-readable media for storing software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the one or more processors, cause the processing system to perform the various functions described in further detail herein.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiments and the concepts contributed by the inventor to furthering the art, and are to be construed as being without limitation to such specifically-recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. An active fluid cooled heatsink assembly for modular components, comprising:
a fluid cooled heatsink, the heatsink further comprising: an inlet, an outlet, and a surface, wherein fluid passing through the heatsink is received by the inlet at a first temperature and expelled from the outlet at a second temperature, wherein the second temperature is higher than the first temperature; and
at least one resource adapter, each resource adapter further comprising a first surface having a shape which conforms to a corresponding electronic resource of at least one electronic resource and a second surface having a shape corresponding to at least a portion of the surface of the fluid cooled heatsink, wherein each resource adapter exchanges heat from the corresponding electronic resource to the fluid cooled heatsink, and wherein the at least one resource adapter is mounted on the surface of the fluid cooled heatsink.

2. The heatsink assembly of claim 1, wherein the fluid includes at least one of: a cooled gas, a liquid, and an engineered fluid.

3. The heatsink assembly of claim 1, wherein the heatsink further comprises a fastener, wherein the fastener couples the heatsink to a resource adapter of the plurality of resource adapters.

4. The heatsink assembly of claim 1, wherein each electronic resource is any of: a storage device, a memory device, a central processing unit (CPU), and a graphics processing unit (GPU).

5. The heatsink assembly of claim 1, wherein the shape of the first surface of a first resource adapter of the at least one resource adapter corresponds to a first electronic resource of the at least one of electronic resource, wherein the shape of the first surface of a second resource adapter of the at least one of resource adapter corresponds to a second electronic resource of the at least one electronic resource, and wherein the shape of the first surface of the first resource adapter is different from the shape of the first surface of the second resource adapter.

6. The heatsink assembly of claim 1, further comprising:
a management module, the management module further comprising an input/output (I/O) interface and a power supply, wherein the I/O interface is operative for connecting to the at least one electronic resource, wherein the power supply is electrically connected to the management module and to a power grid, and wherein the power supply is configured to supply power from the power grid to the management module.

7. The heatsink assembly of claim 6, wherein the management module is configured to:
supply power from the power supply to each of the at least one electronic resource.

8. The heatsink assembly of claim 6, wherein the management module is configured to:
configure a first electronic resource and a second electronic resource of the at least one electronic resource to each transmit an indicator, each indicator indicating that the first electronic resource and the second electronic resource should be connected to each other.

9. The heatsink assembly of claim 8, wherein each indicator includes at least one of: a visual indicator, and an auditory indicator.

10. The heatsink assembly of claim 6, wherein the management module further comprises a network interface controller (NIC).

11. The heatsink assembly of claim 10, wherein the management module is configured to:
provide access, via the NIC, between an electronic resource connected to the management module and a client device connected to a network, wherein the network is a network to which the NIC has access.
